(19) United States
(12) Patent Application Publication
(10) Pub. No.: US 2023/0090366 A1
(43) Pub. Date: Mar. 23, 2023

(54) PIEZOELECTRIC STRUCTURES

(71) Applicant: The MITRE Corporation, McLean, VA (US)

(72) Inventors: Justin E. TUFARIELLO, Concord, MA (US); Leslie Allison RIESENHUBER, Great Falls, VA (US); Alexander J. ANGILELLA, Lexington, MA (US)

(73) Assignee: The MITRE Corporation, McLean, VA (US)

(21) Appl. No.: 17/950,014

(22) Filed: Sep. 21, 2022

Related U.S. Application Data
(60) Provisional application No. 63/247,258, filed on Sep. 22, 2021.

(51) Int. Cl. H04R 17/00; H01L 41/083

(52) U.S. Cl. CPC H04R 17/005; H01L 41/0836

(57) ABSTRACT

A device for transmitting and receiving acoustic waves is provided herein. In one or more examples, the device comprises: a polymer infill; a first set of piezoelectric components, wherein the first set of piezoelectric components comprises one or more piezoelectric components, disposed in a first annular area interstitially in the polymer infill, the first annular area defined by a first inner ring and a first outer ring; a second set of piezoelectric components, wherein the second set of piezoelectric components comprises one or more piezoelectric components, disposed in a second annular area interstitially in the polymer infill, the second annular area defined by a second inner ring and second outer ring; and wherein the rings are spaced apart from each other radially based on one or more Gaussian distributions.

### CROSS-REFERENCE TO RELATED APPLICATIONS

This application claims the benefit of U.S. Provisional Application No. 63/247,258 filed Sep. 22, 2021, the entire contents of which is incorporated herein by reference.

### FIELD OF THE DISCLOSURE

This disclosure generally relates to acoustic communication and detection, and more specifically to underwater communication and detection.

### BACKGROUND OF THE DISCLOSURE

Acoustics are typically preferred for long-range underwater communication and object detection. Alternative forms of communication such as radio frequency and optics are strongly attenuated underwater and therefore are not preferred for most underwater applications. Piezoelectric transducers can be used to communicate and sense underwater signals across a range that spans infrasonic to ultrasonic frequencies. Despite acoustic propagation providing benefits over radio frequency and optical communications for underwater applications, the highly reverberant and refractive underwater channel poses challenges for acoustic communications and sensing. For example, underwater sound waves propagating, especially at long distances (such as hundreds or thousands of feet), bend and scatter on objects in the environment contributing to a higher noise floor and/or convoluting a signal path with a non-linear acoustic channel. The bending and scattering of the underwater sound waves result in diffuse directionality of the underwater sound waves.

Current acoustic systems for underwater applications can be a piezoelectric single aperture for small systems or a piezoelectric phased array for large systems. However, the single aperture structure results in diffuse directionality as described above and the phased array structure must be largely sized to control directionality of the underwater sound waves. Therefore directionality of underwater sounds waves remains a challenge.

### SUMMARY OF THE DISCLOSURE

According to one or more examples, systems and methods for directing underwater sound waves include an active layer (or aperture) of a transducer that includes piezoelectric components as a polymer-infilled composite geometrically arranged to direct acoustic energy in a target direction in an underwater propagation medium. An arrangement of the piezoelectric components that form the piezoelectric structure of the active layer can be positioned according to a Gaussian distribution. By configuring the piezoelectric components according to a Gaussian distribution, the active layer of the transducer can generate a Gaussian-like radiation profile for maximizing waves in an intended direction while minimizing side lobes.

According to one or more examples, a device for transmitting and receiving acoustic waves comprises: a polymer infill; a first set of piezoelectric components, wherein the first set of piezoelectric components comprises one or more piezoelectric components, disposed in a first annular area interstitially in the polymer infill, the first annular area defined by a first inner ring and a first outer ring; a second set of piezoelectric components, wherein the second set of piezoelectric components comprises one or more piezoelectric components, disposed in a second annular area interstitially in the polymer infill, the second annular area defined by a second inner ring and second outer ring; and wherein the rings are spaced apart from each other radially based on one or more Gaussian distributions.

Optionally, spacing of the rings relative to each other may be based on one or more Gaussian distribution functions.

Optionally, the one or more piezoelectric components of the first set of piezoelectric components may be evenly spaced apart from one another in the first annular area, and the one or more piezoelectric components of the second set of piezoelectric components may be evenly spaced apart from one another in the second annular area.

Optionally, the second outer ring may be adjacent and radially inward of the first inner ring, and the first annular area may be defined such that the first outer ring and the first inner ring of the first annular area are equidistant from a first central ring comprising a center of the one or more piezoelectric components of the first set of piezoelectric components and the second annular area may be defined such that the second outer ring and the second inner ring of the second annular area are equidistant from a second central ring comprising a center of the one or more piezoelectric components of the second set of piezoelectric components.

Optionally, a ratio of an area of piezoelectric components of the second annular area to the second annular area may be larger than a ratio of an area of piezoelectric components of the first annulus area to the first annulus area based on one or more Gaussian distributions.

Optionally, the areas of the piezoelectric components and the annular areas between adjacent rings may be the surface area in a circular plane of the device, also referred to as the top view.

Optionally, a first width of the first annular area may be a radius of the first inner ring subtracted from a radius of the first outer ring and a second width of the second annular area may be a radius of the second inner ring subtracted from a radius of the second outer ring, wherein the first width and the second width are equal.

Optionally, the first and second sets of piezoelectric components may be arranged on a radial pattern comprising a center point and the radial pattern may be configured such that fabrication of the device can be accomplished in sections.

Optionally, the device may be configured to generate a radiation pattern comprising a main lobe width of 2 to 20 degrees.

Optionally, the device may include a third set of piezoelectric components wherein the third set of piezoelectric components comprises one or more piezoelectric components, disposed in a third annular area interstitially in the polymer infill, the third annular area may be defined by a third inner ring and a third outer ring.

Optionally, the rings of the third annular area may be spaced apart from each other in the polymer infill based on the one or more Gaussian distributions.

Optionally, piezoelectric components of the first and second sets of piezoelectric components may be identical.

Optionally, piezoelectric components of the first and second sets may be cylindrical pins.

According to one or more examples, a method for manufacturing a device for transmitting and receiving acoustic waves comprises: disposing a first set of piezoelectric components interstitially in a first annular area of a polymer infill, the first annular area defined by a first inner ring and a first outer ring, disposing a second set of piezoelectric components interstitially in a second annular area of the polymer infill, the second annular area defined by a second inner ring and second outer ring, and wherein the rings are spaced apart from each other radially based on one or more Gaussian distributions.

Optionally, spacing of the rings relative to each other is based on one or more Gaussian distribution functions.

Optionally, the one or more piezoelectric components of the first set of piezoelectric components are evenly spaced apart from one another in the first annular area, and the one or more piezoelectric components of the second set of piezoelectric components are evenly spaced apart from one another in the second annular area.

Optionally, the second outer ring is adjacent and radially inward of the first inner ring, and the first annular area is defined such that the first outer ring and the first inner ring of the first annular area are equidistant from a first central ring comprising a center of the one or more piezoelectric components of the first set of piezoelectric components and the second annular area is defined such that the second outer ring and the second inner ring of the second annular area are equidistant from a second central ring comprising a center of the one or more piezoelectric components of the second set of piezoelectric components,

Optionally, a ratio of an area of piezoelectric components of the second annular area to the second annular area is larger than a ratio of an area of piezoelectric components of the first annulus area to the first annulus area based on one or more Gaussian distributions.

Optionally, the areas of the piezoelectric components and the annular areas between adjacent rings are surface area in a circular plane of the device.

Optionally, a first width of the first annular area is a radius of the first inner ring subtracted from a radius of the first outer ring and a second width of the second annular area is a radius of the second inner ring subtracted from a radius of the second outer ring, wherein the first width and the second width are equal.

Optionally, the first and second sets of piezoelectric components are arranged on a radial pattern comprising a center point and the radial pattern is configured such that fabrication of the device can be accomplished in sections.

Optionally, the device is configured to generate a radiation pattern comprising a main lobe width of 2 to 20 degrees.

Optionally, the method comprises disposing a third set of piezoelectric components interstitially in the polymer infill, wherein the third set of piezoelectric components comprises one or more piezoelectric components, and wherein the third set of piezoelectric components are disposed in a third annular area interstitially in the polymer infill, the third annular area defined by a third inner ring and a third outer ring.

Optionally, the rings of the third annular area are spaced apart from each other in the polymer infill based on the one or more Gaussian distributions.

Optionally, piezoelectric components of the first and second sets of piezoelectric components are identical.

Optionally, piezoelectric components of the first and second sets are cylindrical pins.

### BRIEF DESCRIPTION OF THE DRAWINGS

The disclosure will now be described, by way of example only, with reference to the accompanying drawings, in which:

FIG. 1A shows a top view of an exemplary columnar 1-3 piezoelectric composite test transducer that includes a piezoelectric structure fabricated through a first manufacturing process;

FIG. 1B shows a top view of an exemplary columnar 1-3 piezoelectric composite test transducer that includes a piezoelectric structure fabricated through a second manufacturing process;

FIG. 2A shows a top view of computer-aided design (CAD) model of an exemplary piezoelectric structure layer of a transducer with a radial Gaussian distribution, according to one or more examples of the disclosure;

FIG. 2B depicts ring formation of a radial Gaussian distribution, according to some examples;

FIG. 2C depicts exemplary ring spacing of a radial Gaussian distribution, according to one or more examples of the disclosure;

FIG. 2D shows a perspective view of a piezoelectric structure, according to one or more examples of the disclosure;

FIG. 2E illustrates another exemplary view of a piezoelectric structure, according to one or more examples of the disclosure.

FIG. 2F illustrates another exemplary view of a piezoelectric structure, according to one or more examples of the disclosure.

FIG. 2G illustrates another exemplary view of a piezoelectric structure, according to one or more examples of the disclosure.

FIG. 3A shows an example displacement surface from a finite element analysis simulation of a polar radiation pattern of the piezoelectric structure, according to some examples; and

FIG. 3B shows an example of a normalized polar radiation pattern comparing curves generated from a piezoelectric structure comprising Gaussian distributed pins (dashed line) and another piezoelectric structure comprising evenly distributed pins (solid line), according to some examples.

### DETAILED DESCRIPTION

Devices, systems, and methods according to various examples described herein include piezoelectric components of a piezoelectric structure positioned for controlling directivity of sound waves propagating underwater. The piezoelectric components can include a plurality of pins spaced relative to each other based on one or more Gaussian distribution functions. By utilizing the piezoelectric components as a piezoelectric structure for an active layer of a transducer, underwater sound waves can be pointed and mechanically steered providing focused directionality of the sound waves. In this way, underwater sound waves can be isolated to reach an intended target as evidenced by minimal side lobes in corresponding radiation patterns.

In addition, it is also to be understood that the singular forms “a”, “an,” and “the” used in the following description are intended to include the plural forms as well, unless the context clearly indicates otherwise. It is also to be understood that the term “and/or,” as used herein, refers to and encompasses any and all possible combinations of one or more of the associated listed items. It is further to be understood that the terms “includes,” “including,” “comprises,” and/or “comprising,” when used herein, specify the presence of stated features, integers, steps, operations, elements, components, and/or units, but do not preclude the presence or addition of one or more other features, integers, steps, operations, elements, components, units, and/or groups thereof.

In the following description of the disclosure and examples, reference is made to the accompanying drawings in which are shown, by way of illustration, specific examples that can be practiced. It is to be understood that other examples and examples can be practiced, and changes can be made, without departing from the scope of the disclosure.

Described herein are examples of development, fabrication, validation, and testing of piezoelectric structures configured for underwater applications for small platforms such as portable underwater system and unmanned underwater systems. As described further below, the piezoelectric structures can be developed (and validated) to provide improved performance compared to conventional structures for underwater applications prior to physical prototyping. The piezoelectric structures can include piezoelectric components fabricated from one or more pieces of a piezoelectric material.

According to some examples, determined piezoelectric structures that are expected to achieve target properties can be fabricated via a particular manufacturing process to realize a physical piezoelectric active layer. According to some examples, development of the piezoelectric structures can include finite element analysis and modeling tools to determine at least one of the following: (1) the behavior of composite piezoelectric structures that are expected to achieve targeted acoustic and impedance results and (2) whether a particular manufacturing process of the piezoelectric structures is suitable for underwater application and comparable to conventional piezoelectric structures on a bulk scale.

According to some examples, the determined piezoelectric structures can be fabricated using processes such as additive manufacturing, injection molding, and dice and fill. According to some examples, the manufacturing process may contribute to enhanced properties (such as augmented transducer directivity, bandwidth, and sensitivity) of the developed piezoelectric structures. To characterize a magnitude of such enhancements, finite element analysis can be used to model manufactured piezoelectric structures and predict performance prior to physical prototyping.

According to some examples, the determined piezoelectric structures can be fabricated with additive manufacturing using a printer. The green part is the state of a part immediately after printing. Post-processing steps of the green part can include densifying and imparting an electric dipole. The printer can be used to print a wide variety of geometries for a variety of determined piezoelectric structures that can include different layer areas and orientations. For example, the geometries can include bars and discs in horizontal and vertical build orientations, lattices, and combs. The printer can be capable of printing geometries with footprint widths ranging from half a millimeter to 2.4 inches at about 1 to 2 cubic mm per second with a 10 micron layer thickness. According to some examples, simulation of smaller geometries can achieve side lobe results comparable to larger structures, however the smaller structure require a printer with higher manufacturing resolution.

A manufacturing process chosen to fabricate the determined piezoelectric structures can be validated to ensure the manufacturing process is capable of delivering a piezoelectric test material that is comparable with expected bulk properties of that material. The manufacturing process can also be validated by ensuring that test structures utilizing fabricated piezoelectric test structures achieve comparable performance as other manufacturing process. That is two or more manufacturing processes can be compared to assess material properties of fabricated test pieces and acoustic measurements of transducers made with fabricated test structures.

A manufacturing process chosen to fabricate the determined piezoelectric structures can be validated by fabricating a test piece of a piezoelectric material to ensure that the fabricated test piece achieves expected properties of a corresponding bulk piezoelectric material. The validation can be done prior to physical prototyping of a complete transducer determined to ensure that a structure printed from a piezoelectric slurry material exhibits expected material properties. Example material properties can include density which may be indicative of uniformity of the printing, dielectric constant (k) which is a measure of capacitance of the material, and charge coefficient (d33, also referred to as the piezoelectric coefficient) which is a measure of mechanical strain per unit of applied electrical field. As dictated by the piezoelectric effect, when a piezoelectric material is deformed, an electrical field is generated such that the material can be driven with the electric field to create pressure waves in water or air or to sense pressure waves in acoustic media by measuring voltage from a piezoelectric material. The charge coefficient indicates the magnitude of such piezoelectric effects. The validation measurements can be performed on printed IEEE test geometries (such as 86 ANSI/IEEE Std 176-1987 test geometries) based on a standardized specifications to isolate fundamental resonance modes. An example of an empirical comparison between material properties of a printed test geometry of an exemplary piezoelectric material and expected theoretical values of the exemplary piezoelectric material is shown in Table 1 below.

TABLE 1
Material properties of a printed test geometry
of Lead Zirconate Titanate (PZT-5H)

| | Density [g/cc] | k | d₃₃ [pC/N] |
|---|---|---|---|
| Theoretical values | 7.5 | 3400 | 593 |
| Measured Mean (μ) | 7.51 | 3476.9 | 705.5 |
| Measured standard | 0.22 | 258.5 | 47.8 |
| deviation (σ) | | | |

Table 1 indicates excellent agreement between theoretical parameters of Lead Zirconate Titanate (PZT-5H) and the fabricated PZT-5H material. The measured mean and standard deviation is based on a plurality of samples for a particular fabrication protocol. In the example of Table 1, the fabrication protocol involves a particular slurry formulation for additive manufacturing. A slurry formulation is a source material for the printed piezoelectric structure. The slurry formulation can be configured to deliver precise material properties of printed piezoelectric material that are agnostic to geometry and comparable to bulk piezoelectric materials. Such material properties can include a target piezoelectric coefficient and a target dielectric constant suitable for underwater applications.

A manufacturing process chosen to fabricate the determined piezoelectric structures can be validated by fabricating and comparing a first test transducer fabricated using a first manufacturing process and a second test transducer fabricated using a second manufacturing process. The first test transducer and the second test transducer may include a same target piezoelectric structure such that the variable is the manufacturing process.

The validation process of the manufacturing process described herein can serve as a proof of concept that a chosen manufacturing process delivers piezoelectric structures with repeatability prior to physically prototyping structures that have not been previously characterized.

As described above, test transducers that include a same targeted piezoelectric structure can be compared to validate a manufacturing process. An example test transducer can be a columnar piezoelectric composite transducer created from a piezoelectric ceramic encapsulated by a non-piezoelectric polymer. An example arrangement of piezoelectric structure is a 1-3 arrangement. A 1-3 arrangement can be any arrangement of straight columns lined up parallel filled in with a polymer. Specifically, the first number (1) refers to the dimensions of connectivity (maximally 3) of the ceramic material phase. Since the ceramic material phase in a 1-3 arrangement is only continuous through the Z unit direction (in an X,Y,Z Cartesian vector frame), there is only 1 dimension of connectivity. The second number (3) refers to polymer phase connectivity. Since the polymer phase connects across X,Y, and Z in a 1-3 arrangement, there are 3 dimensions of connectivity.

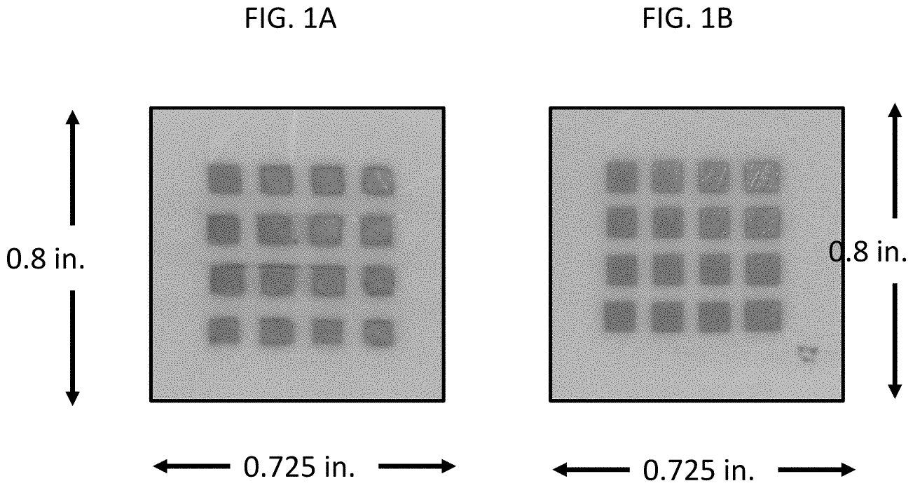

A first test transducer can include a targeted piezoelectric test structure fabricated using a first manufacturing process and a second test transducer can include the target piezoelectric test structure fabricated using a second manufacturing process. FIG. 1A shows a top view of an exemplary columnar 1-3 piezoelectric composite test transducer that includes a piezoelectric structure fabricated by a first manufacturing process. FIG. 1B shows a top view of an exemplary columnar 1-3 piezoelectric composite test transducer that includes a piezoelectric structure fabricated by a second manufacturing process. In FIGS. 1A and 1B, the darker color shade shows the piezoelectric material (such as PZT) and the lighter shade shows a non-piezoelectric polymer that encapsulates the piezoelectric material. Each test transducer can be evaluated to determine a fundamental resonance, a PZT volume fraction, in-air impedance measurements, and in-water sensitivity measurements of each test transducer. Generally, a local minimum in the impedance measurements (impedance magnitude vs. frequency) can represent the resonance frequency of a transducer. The resonance frequency is a fundamental frequency in which the transducer operates. In-water sensitivity measurements can include transmitting voltage response (TVR) and receive voltage sensitivity (RVS). The TVR and RVS can be measured in an anechoic acoustic test tank.

Agreement between the fundamental resonance, PZT volume fraction, impedance measurements, and sensitivity measurements of the first test transducer and the second test transducer can be indicative that both of the manufacturing processes deliver similar piezoelectric test structure with similar performance. For example, if the impedance measurements indicate a same resonance frequency and the sensitivity measurements are within a reasonable noise range (for example, such as 3 dB) in both transmit and receive applications, then the measurements of the first and the second test transducers are in good agreement with each other. This validates that a particular manufacturing process does not introduce anomalies, unexpected behavior, or unrepeatable results.

Described above are proof of concept procedures that can be used to validate that (1) a manufacturing process can fabricate a piezoelectric material having material properties in agreement with theoretical values for the piezoelectric material and (2) performance of a test transducer that includes a test piezoelectric structure fabricated by a first manufacturing process is in agreement with performance of a test transducer that include a test piezoelectric structure fabricated by a second manufacturing process. Now, this disclosure will describe target piezoelectric structures fabricated from a manufacturing process. According to some examples, the manufacturing process can include additive manufacturing, injection molding, and dice and fill.

According to some examples, the manufacturing process can be used to fabricate spatially distributed apertures, periodic 3-3 composite and auxetic structures. Complex geometries can enhance acoustic performance of transducers that utilize the complex geometries. For the example of spatially distributed apertures, an apodized surface velocity achieved through a Gaussian distribution of piezoelectric materials can yield increased side lobe mitigation compared with uniform radiating apertures. In this way, a piezoelectric structure can be configured for energy focusing and directional sensing underwater through apodized geometry of an active layer of a transducer. The active layer of the transducer can be a piezocomposite that includes the piezoelectric structure and a polymer that at least partially encapsulates the piezoelectric structure. According to some examples, the piezoelectric structure can include piezoelectric components made of piezoelectric ceramic. According to some examples, example polymers include polyurethane and various epoxy resins. According to some examples, the polymer can be non-piezoelectric.

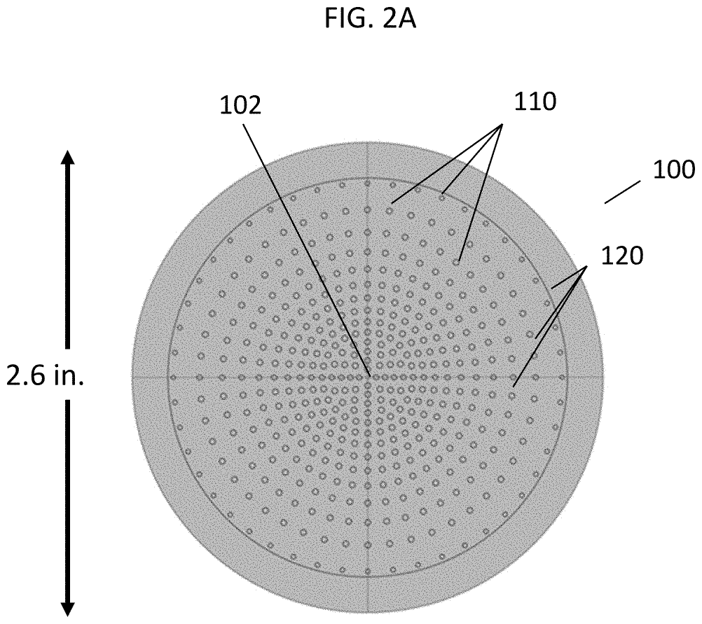

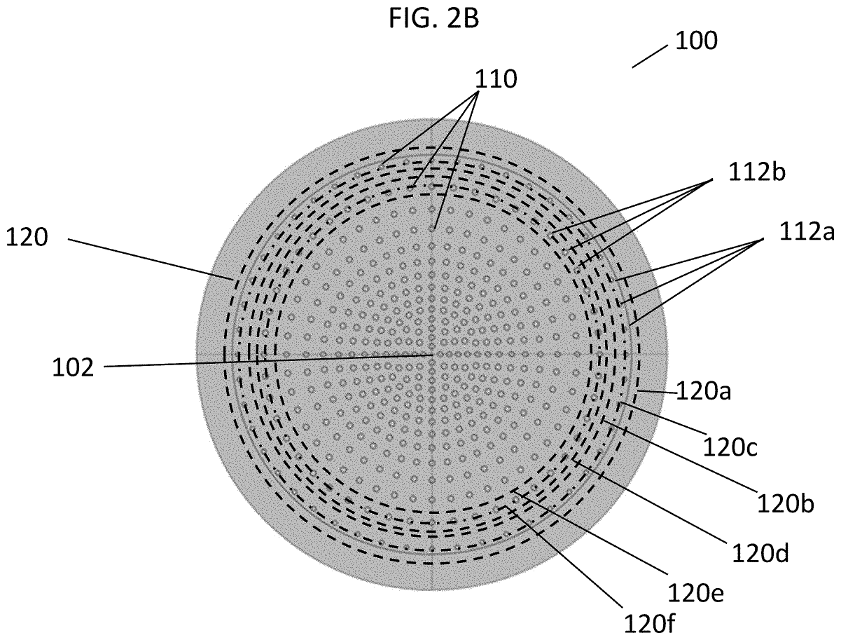

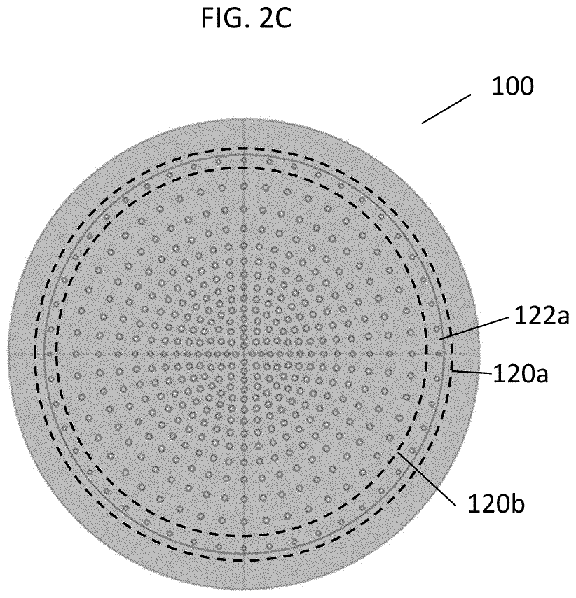

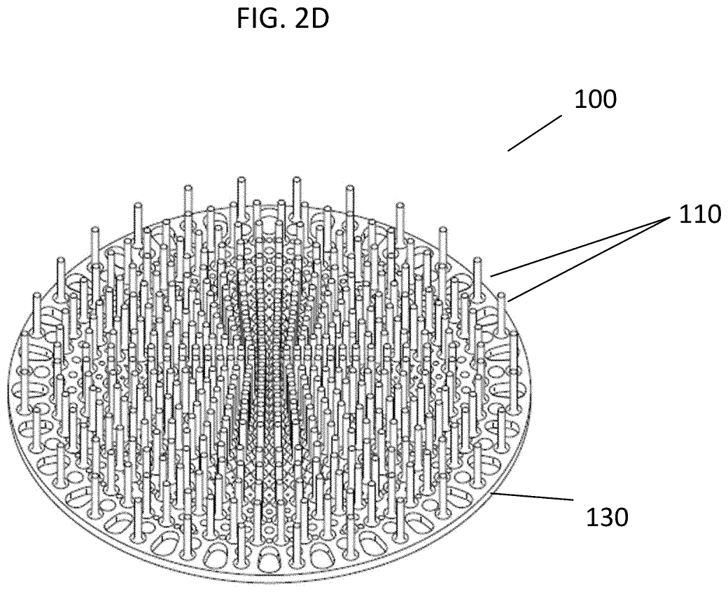

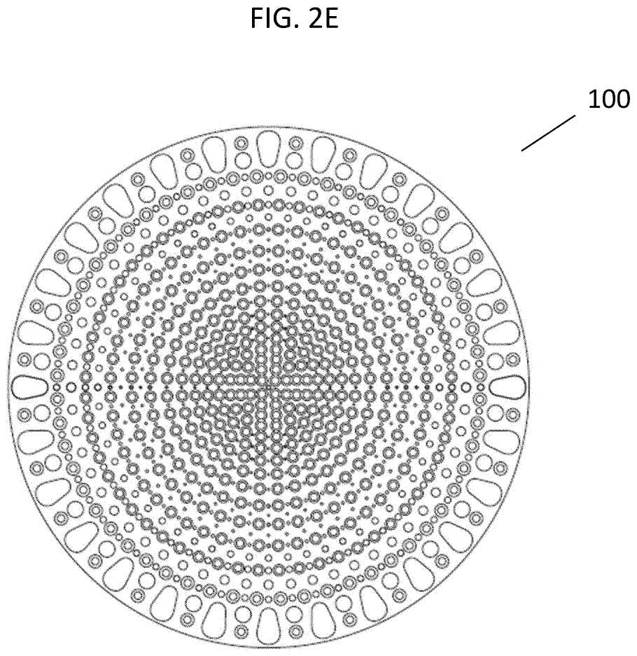

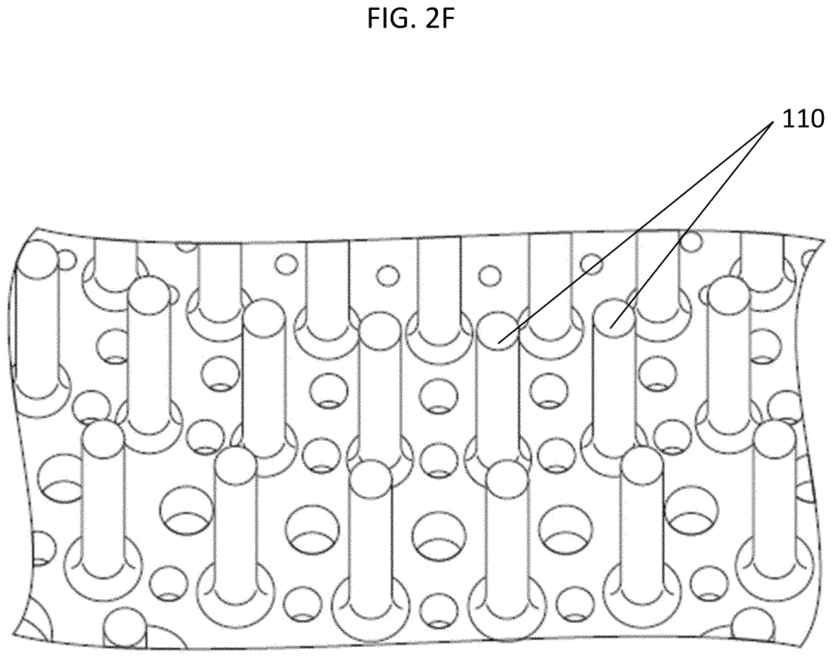

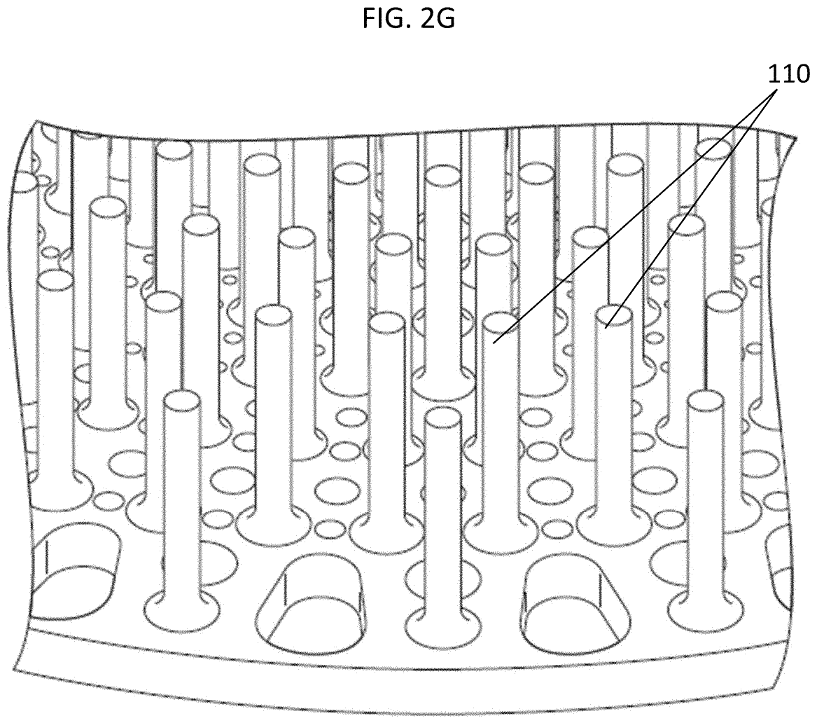

A piezoelectric structure layer of a transducer can be simulated using 3D modeling and performance of the transducer can be simulated using engineering simulation software. According to some examples, the structure layer can include a polymer infill and piezoelectric components. FIG. 2A shows a top view of computer-aided design (CAD) model of an exemplary piezoelectric structure layer of a transducer with a radial Gaussian distribution, according to some examples. The piezoelectric structure 100 includes a plurality of piezoelectric components 110 (described hereafter as pins) arranged in rings spaced according to one or more Gaussian distribution functions. According to some examples, a total number of pins 110 can be from about 204 to 456—this range is an example only and should not be seen as limiting the invention. In the example of FIG. 2A, a total number of pins in the example is 456 and is used for example only and should not be seen as limiting the invention. According to some examples, the plurality of pins 110 can include sets of pins each arranged on a corresponding ring. According to some examples, a number of sets of pins can be at least 8, 10, or 12. According to some examples, a number of sets of pins can be at most 20, 18, or 16. According to some examples, a number of sets of pins can be at least 8 to 20, 10 to 18, or 12 to 16. The rings are shown in FIG. 2B for illustrative purposes only. According to some examples, a first set of pins 112a of the plurality of pins 110 can be arranged in a first annular area ring formed by rings 120a and 120b such that a center of each pin is centered on ring 120c (dash-dot line). A second set of pins 112b of the plurality of pins 110 can be arranged in a second annular area formed by rings 120d and 120e such that a center of each pin is centered on ring 120f (dash-dot line), and so forth and so on. Each set of pins of the plurality of pins 110 can be evenly spaced in its corresponding annular area on central rings such as 120c and 120f. According to some examples, each ring can be spaced from each other based on a Gaussian distribution. According to some examples, the proportion of pin area to annulus ring area increases towards a center point 102 of a pin pattern based on a Gaussian distribution. The annulus area is formed by two adjacent rings. According to some examples, a pin area and an annulus area are surface area in the circular plane of a transducer. According to some examples, an inner ring of the first annular area can be the same as an outer ring of the second annular area. According to some examples, a width of the first annular area and a width of the second annular areas may the same. According to some examples, all annular areas of the ring pattern may have the same width.

According to some examples, there are two Gaussian distributions of the ring pattern. For example the spacing of the rings relative to each other can follow a Gaussian function, getting closer to each other towards the center of the ring pattern. According to some examples, a second Gaussian distributed can be associated with an area ratio defined as the pin area in an annular ring divided by an area of the annular ring area. This area ratio can increase towards the center in a Gaussian manner. According to some examples, these are two distinct Gaussian functions.

FIG. 2C depicts exemplary of ring spacing of a radial Gaussian distribution, according to some examples. In the example of FIG. 2C, a first annular area 122a is formed by a first outer ring 120a and a first inner ring 120b. The first annular area 122a can include a first area of pins 110 in the first annular area 122. According to some examples, each radial ring of pins can be positioned within an area of a respective annular ring and a ratio of an area of the pins in a particular annular area to the area of the particular annular area increases towards a center point 102 of the radial pattern. FIGS. 2A-2B shows examples of two annular rings. FIG. 2D shows a perspective view of the piezoelectric structure 100, according to some examples.

According to some examples, each piezoelectric pin of a transducer can have a same shape and uniform thickness. For example, the pins can be circular, rectangular, or polygonal. In the example of FIG. 2D, the pins 110 have a circular cylindrical shape with a length of about 8 mm. The circular cylindrical shape and 8 mm length of FIG. 2D are used for example only and should not be seen as limiting the invention. The length of the pins shown in FIG. 2D can be an intermediate length which can be shortened by post-processing such as sintering and grinding. According to some examples, a length and a diameter of each pin may be chosen to be as small as possible and may be limited based on resolution of the manufacturing process and mechanical stability during post processing. According to some examples, a length of the pins 110 can be at least 1 mm, 2 mm, 4 mm, or 6 mm. According to some examples, a length of the pins 110 can be at most 30 mm, 20 mm, 16mm, 14 mm, 12 mm, or 10 mm. According to some examples, a length of the pins 110 can be 1 mm to 30 mm, 2 mm to 20 mm, 4 mm to 16 mm, or 6 mm to 12 mm, or 4 mm to 10 mm.

The diameter and thickness (length) of the transducer can be configured based on underwater application. In the example of FIG. 2A, a diameter of the transducer is 2.6 inches with a thickness configured for a thickness-mode resonance frequency of approximately 250 kHz. The diameter of 2.6 inches of FIG. 2A is used for example only and should not be seen as limiting the invention. According to some examples, a diameter of the transducer can be at least 1 inch, at least 1.5 inches, or at least 2 inches. According to some examples, a diameter of the transducer can be at most 6 inches, at most 5 inches, or at most 4 inches. According to some examples, a diameter of the transducer can be 1 inch to 6 inches, 1.5 inches to 5 inches, or 2 inches to 6 inches. According to some examples, a thickness of the transducer can be configured for a thickness-mode frequency of 60 kHz to 3 MHz. According to some examples, a thickness of the transducer can be configured for a thickness-mode frequency of 60 kHz to 20 MHz. FIG. 2E illustrates another exemplary view of a piezoelectric structure, according to one or more examples of the disclosure. The view provided by FIG. 2E provides a top view of the the piezoelectric structure 100. FIGS. 2F-G illustrate another exemplary view of a piezoelectric structure, according to one or more examples of the disclosure. In one or more examples, the views provided in FIGS. 2F show a close up view of the pins 110 of the piezoelectric structure 100.

According to some examples, one or more Gaussian distribution functions can be used to determine placement of pins 110. For example, the pins 110 can be placed in a radial ring pattern 120. The ring pattern 120 can include a plurality of concentric rings (depicted in FIG. 2B) that decrease in diameter towards the center point 102 of the ring pattern 120. The decrease in diameter towards the center point 102 allows adjacent rings of the ring pattern 120 to be spaced from each other. According to some examples, the decrease in diameter of each adjacent ring is determined based on a Gaussian distribution function. According to some examples, the decrease in spacing between each adjacent ring is determined based on a Gaussian distribution function. According to some examples, the pins 110 may be placed such that a proportional area of the pins 110 within the ring pattern 120 is configured to increase towards the center point 102 based on a Gaussian distribution function. According to some examples, the area of the pins 110 refers to the portion of the area of the pins 110 that cover the ring pattern 120 (for example, from a top view). According to some examples, one or more pins of pins 110 may be different from other pins 110 in shape or size. For identical pins that are circular cylinders, the area of the pins 110 covering the ring pattern 120 is proportional to a number of pins multiplied by the square of an individual pin's radius According to some examples, layout of the pins 110 can be configured such that fabrication (such as printing) of the piezoelectric structures can be accomplished in sections (such as quadrants) to ease fabrication.

According to some examples, a ratio of an area of the pins 110 of a particular annulus divided by an area of the particular ring annulus) can increase towards the center point 102 based on a Gaussian distribution function. The area of pins 110 of a particular annulus may be defined by pins that are arranged in rings that define the particular annulus area. According to some examples, an area fraction (surface area of piezoelectric pins 110 vs. polymer) can increase toward the center based on a Gaussian distribution function.

According to some examples, a number of the pins 110 may decrease or increase towards the center point 102 based on a Gaussian distribution function. According to some examples, each ring of the ring pattern 120 may include a different number of pins of the pins 110 such that an area of the pins 110 divided by the area of the annulus increases towards the center point 102 based on a Gaussian distribution function. Along each ring of the ring pattern 120, the pins 110 may be evenly spaced.

Variance of the one or more Gaussian distribution functions can be dependent on aperture size achievable which is limited by the manufacturing process of the aperture. According to some examples, the variance of the one or more Gaussian distributions for pin placement can be proportional to size of an aperture of a transducer and desirable main lobe width of a corresponding radiation pattern. The desirable main lobe width can be determined based on an underwater application and type of directivity desired for the underwater applications. According to some examples, the variance can be determined empirically. According to some examples, the variance of the one or more Gaussian distribution functions of the piezoelectric structure 100 can be determined based one or more of finite element analysis and trial and error.

In the example of FIG. 2D, the pins 110 are shown supported on a substrate 130. However, during fabrication of transducers that include pins 110, the pins 110 can be at least partially encapsulated in non-piezoelectric polymer and the substrate 130 can be removed.

The pins 110 can be distributed according to one or more Gaussian distribution functions to achieve a radiation response that corresponds with directed energy to and from a target with minimal energy transmitted or received by unintended targets. In theory, a continuous spatial Fourier transform (2D) of a Gaussian distribution is a Gaussian distribution having no side lobes. In other words, a perfect continuous Gaussian distribution can represent energy focused only at an intended target and nothing else. However, in reality, although a fabricated structure can be configured to mimic a continuous distribution to some extent, the fabricated structure is discrete. It is the discrete nature that contributes to generation of side lobes. As described herein, the piezoelectric structure 100 can be fabricated based one or more Gaussian distribution functions to configure the piezoelectric structure 100 to approach the continuous limit as feasibly possible.

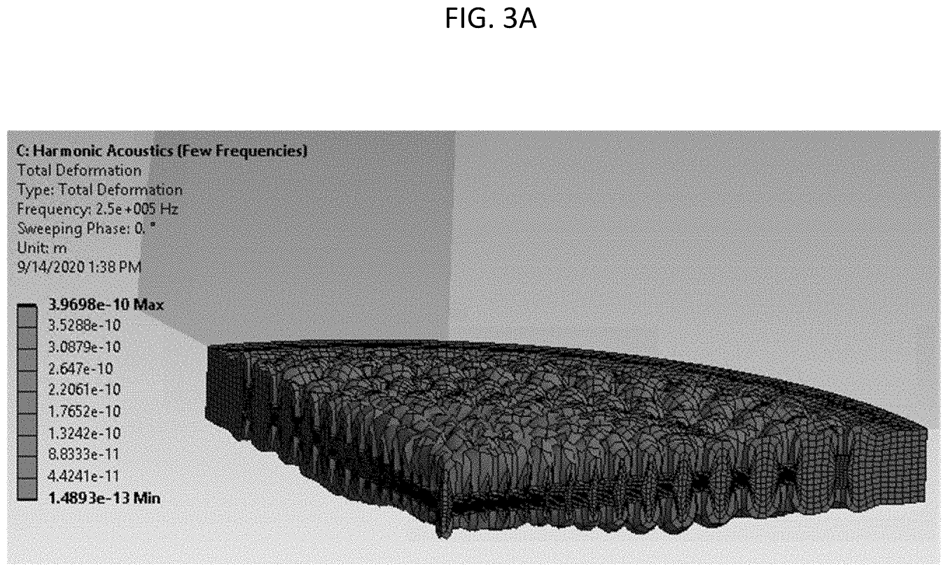

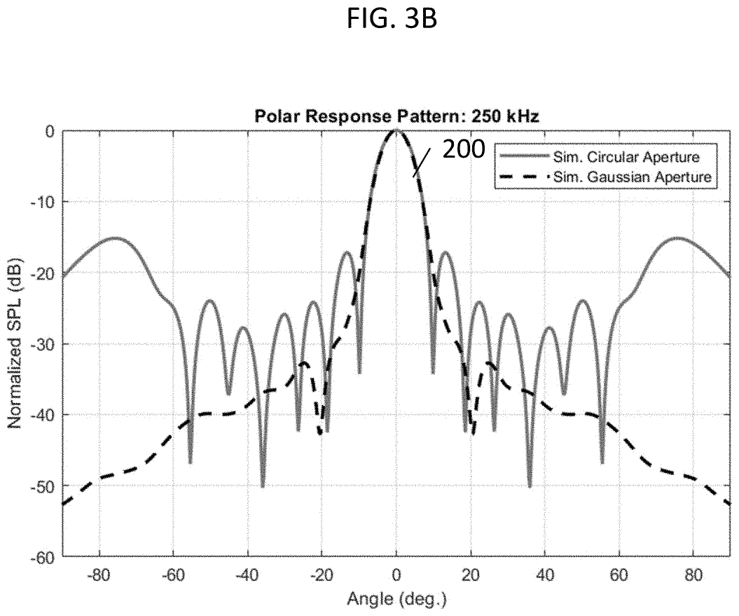

FIG. 3A shows an example displacement surface from a finite element analysis simulation of polar radiation pattern of the piezoelectric structure of FIG. 2D that is sized to achieve a resonance frequency near 250 Hz. The driving frequency of 250 Hz of FIG. 3A is used for example only and should not be seen as limiting the invention. According to some examples, pin thickness, material, or volume fraction can be changed to achieve other target resonance frequencies depending on underwater application. The polymer material selection also affects frequency. Pin spacing can be altered to tailor surface apodization. Generally, thinner piezoelectric structures result in higher resonance frequencies. According to some examples, the finite element analysis can be used to compute a far field acoustic radiation pattern at the intended resonance frequency. In the example of FIG. 3A, the displacement profile is at 250 kHz.

A Gaussian transducer (also referred to as a Gaussian aperture) can include a piezoelectric composite that includes the Gaussian distributed pins 110 and a polymer configured to at least partially encapsulate the pins 110. Likewise, a circular transducer (also referred to as a circular aperture) can include a piezoelectric composite that includes evenly distributed pins at least partially encapsulated by a polymer. In a circular aperture, the pins can be evenly spaced from each other on concentric rings that are evenly spaced from each other. FIG. 3B shows an example of a normalized polar radiation pattern comparing curves generated from a piezoelectric structure comprising Gaussian distributed pins (dashed line) and another piezoelectric structure comprising evenly distributed pins (solid line), according to some examples. The Gaussian distributed pins can be pins 110 as shown in FIG. 2D. In FIG. 3B, the y-axis represents a normalized sound level (normalized based on maximum pressure magnitude) and the x-axis represents an angle theta in which energy can be directed. A larger sound level at an angle theta is indicative of more energy being directed in a direction of the angle theta. Due to normalization, in the example of FIG. 3B, the loudest sound level communicated or sensed is indicated by 0 dB.

FIG. 3B shows that a Gaussian distributed pin pattern achieves a side lobe attenuation in a range from 9 dB to greater than 40 dB compared to a uniform circular 1-3 piezocomposite pin pattern with matching main lobe widths of 8.4 degrees. That is, the main lobe widths of the Gaussian aperture and the circular aperture are the same, however, the Gaussian aperture yields much larger side lobe rejections indicated by null peak pattern off of the 0 theta value. Therefore, FIG. 3B shows that the Gaussian pin pattern (such as that shown in FIG. 2D) yields significant energy focusing (via main lobe 200) and can outperform conventional patterns such as circular pin patterns. The side lobe attenuation of FIG. 3B is used for example only and should not be seen as limiting the invention.

In communication systems, minimized side lobes enable a more direct and isolated communication. For example, in an ideal communication system, energy can be primarily directed (depicted by a main lobe of a radiation pattern) such that only the intended target receives the energy and one or more unintended targets (depicted by side lobes of a radiation pattern) do not. Similarly, in sensing systems, minimized side lobes enable aiming at an intended target and receiving from the intended target. For example, in an ideal sensing system, the system can transmit energy to an intended target and receive return energy from only the intended target (depicted by a main lobe of a radiation pattern) such that return energy from one or more unintended targets (depicted by side lobes of a radiation pattern) are not received by the system. In communication and sensing systems, the side lobes' energy directions can result in ambiguity or misinformation regarding distinctions between energy transmitted/received in the main lobe directions and in the side lobe energy directions.

A desirable level of energy focusing can be achieved based on piezoelectric pin placement in an active layer of a transducer. The desirable level of energy focusing can be characterized by a desirable main lobe with an acceptable side lobe height for a given underwater application. The main lobe width and the side lobe height are inversely proportional. For example, for a wide main lobe width, the side lobes can be mitigated. Conversely, for a narrow main lobe width, the side lobe heights increase. The size of the aperture limits where a variance number that achieves a desirable main lobe width is placed in the distribution function. According to some examples, a Gaussian distribution described herein of piezoelectric materials can achieve desirable results for focusing energy via the main lobe and reducing side lobes for underwater application.

As shown in FIG. 3B, the piezoelectric structure 100 (shown in FIGS. 2A and 2D) is configured to achieve a desirable main lobe width less than 10 degrees, according to some examples. However, the main lobe width can be dependent on pin size and placement. The main lobe width of less than 10 degrees of FIG. 3B is used for example only and should not be seen as limiting the invention. According to some examples, for a given application, the pin size and placement can be configured to achieve a desirable main lobe width of at least 2 degrees, 6 degrees, or 8 degrees. According to some examples, the pin size and placement can be configured to achieve a desirable main lobe width of at most 20 degrees, 15 degrees, or 12 degrees. According to other examples, the pin size and placement can be configured to achieve a desirable main lobe width of 2 degrees to 20 degrees, 6 degrees to 15 degrees, or 8 degrees to 12 degrees.

According to some examples, the piezoelectric structure described herein can include one or more Gaussian distributions to achieve reduction in side lobes in the radiation of a transducer device. This means that the transducer can focus energy without putting as much in unwanted directions—the energy can be guided in one singular direction or in a narrow range of directions. According to some examples, a narrow range of direction can be up to about 20 degrees. For underwater applications, this focused energy allows for very intentional direction of acoustic communication and intentional sensing based on where the acoustic sensing beam is pointed. According to some examples, the transducer can be configured to achieve augmented transducer directivity, bandwidth, and sensitivity based at least on the piezoelectric structure of an active layer of the transducer.

The foregoing description, for the purpose of explanation, has been described with reference to specific examples. However, the illustrative discussions above are not intended to be exhaustive or to limit the invention to the precise forms disclosed. Many modifications and variations are possible in view of the above teachings. The examples were chosen and described in order to best explain the principles of the techniques and their practical applications. Others skilled in the art are thereby enabled to best utilize the techniques and various examples with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

1. A device for transmitting and receiving acoustic waves, comprising:
a polymer infill;
a first set of piezoelectric components, wherein the first set of piezoelectric components comprises one or more piezoelectric components, disposed in a first annular area interstitially in the polymer infill, the first annular area defined by a first inner ring and a first outer ring;
a second set of piezoelectric components, wherein the second set of piezoelectric components comprises one or more piezoelectric components, disposed in a second annular area interstitially in the polymer infill, the second annular area defined by a second inner ring and second outer ring; and
wherein the rings are spaced apart from each other radially based on one or more Gaussian distributions.

2. The device of claim 1, wherein spacing of the rings relative to each other is based on one or more Gaussian distribution functions.

3. The device of claim 1, wherein the one or more piezoelectric components of the first set of piezoelectric components are evenly spaced apart from one another in the first annular area, and the one or more piezoelectric components of the second set of piezoelectric components are evenly spaced apart from one another in the second annular area.

4. The device of claim 1, wherein the second outer ring is adjacent and radially inward of the first inner ring, and the first annular area is defined such that the first outer ring and the first inner ring of the first annular area are equidistant from a first central ring comprising a center of the one or more piezoelectric components of the first set of piezoelectric components and the second annular area is defined such that the second outer ring and the second inner ring of the second annular area are equidistant from a second central ring comprising a center of the one or more piezoelectric components of the second set of piezoelectric components,

5. The device of claim 1, wherein a ratio of an area of piezoelectric components of the second annular area to the second annular area is larger than a ratio of an area of piezoelectric components of the first annulus area to the first annulus area based on one or more Gaussian distributions.

6. The device of claim 5, wherein the areas of the piezoelectric components and the annular areas between adjacent rings are surface area in a circular plane of the device.

7. The device of claim 1, wherein a first width of the first annular area is a radius of the first inner ring subtracted from a radius of the first outer ring and a second width of the second annular area is a radius of the second inner ring subtracted from a radius of the second outer ring, wherein the first width and the second width are equal.

8. The device of claim 1, wherein the first and second sets of piezoelectric components are arranged on a radial pattern comprising a center point and the radial pattern is configured such that fabrication of the device can be accomplished in sections.

9. The device of claim 1, wherein the device is configured to generate a radiation pattern comprising a main lobe width of 2 to 20 degrees.

10. The device of claim 1, the device comprising a third set of piezoelectric components wherein the third set of piezoelectric components comprises one or more piezoelectric components, disposed in a third annular area interstitially in the polymer infill, the third annular area is defined by a third inner ring and a third outer ring.

11. The device of claim 10, wherein the rings of the third annular area are spaced apart from each other in the polymer infill based on the one or more Gaussian distributions.

12. The device of claim 1, wherein piezoelectric components of the first and second sets of piezoelectric components are identical.

13. The device of claim 1, wherein piezoelectric components of the first and second sets are cylindrical pins.

14. A method for manufacturing a device for transmitting and receiving acoustic waves,
the method comprising:
disposing a first set of piezoelectric components interstitially in a first annular area of a polymer infill, the first annular area defined by a first inner ring and a first outer ring;
disposing a second set of piezoelectric components interstitially in a second annular area of the polymer infill, the second annular area defined by a second inner ring and second outer ring; and
wherein the rings are spaced apart from each other radially based on one or more Gaussian distributions.

15. The method of claim 14, wherein spacing of the rings relative to each other is based on one or more Gaussian distribution functions.

16. The method of claim 14, wherein the one or more piezoelectric components of the first set of piezoelectric components are evenly spaced apart from one another in the first annular area, and the one or more piezoelectric components of the second set of piezoelectric components are evenly spaced apart from one another in the second annular area.

17. The method of claim 14, wherein the second outer ring is adjacent and radially inward of the first inner ring, and the first annular area is defined such that the first outer ring and the first inner ring of the first annular area are equidistant from a first central ring comprising a center of the one or more piezoelectric components of the first set of piezoelectric components and the second annular area is defined such that the second outer ring and the second inner ring of the second annular area are equidistant from a second central ring comprising a center of the one or more piezoelectric components of the second set of piezoelectric components,

18. The method of claim 14, wherein a ratio of an area of piezoelectric components of the second annular area to the second annular area is larger than a ratio of an area of piezoelectric components of the first annulus area to the first annulus area based on one or more Gaussian distributions.

19. The method of claim 18, wherein the areas of the piezoelectric components and the annular areas between adjacent rings are surface area in a circular plane of the device.

20. The method of claim 14, wherein a first width of the first annular area is a radius of the first inner ring subtracted from a radius of the first outer ring and a second width of the second annular area is a radius of the second inner ring subtracted from a radius of the second outer ring, wherein the first width and the second width are equal.

21. The method of claim 14, wherein the first and second sets of piezoelectric components are arranged on a radial pattern comprising a center point and the radial pattern is configured such that fabrication of the device can be accomplished in sections.

22. The method of claim 14, wherein the device is configured to generate a radiation pattern comprising a main lobe width of 2 to 20 degrees.

23. The method of claim 14, the method comprising disposing a third set of piezoelectric components interstitially in the polymer infill, wherein the third set of piezoelectric components comprises one or more piezoelectric components, and wherein the third set of piezoelectric components are disposed in a third annular area interstitially in the polymer infill, the third annular area defined by a third inner ring and a third outer ring.

24. The method of claim 23, wherein the rings of the third annular area are spaced apart from each other in the polymer infill based on the one or more Gaussian distributions.

25. The method of claim 14, wherein piezoelectric components of the first and second sets of piezoelectric components are identical.

26. The method of claim 14, wherein piezoelectric components of the first and second sets are cylindrical pins.
